(19) United States
(12) Patent Application Publication
(10) Pub. No.: US 2021/0341382 A1
(43) Pub. Date: Nov. 4, 2021

(54) LASER DEVICE FOR POLARISATION INTERFEROMETRY

(71) Applicants: Université de Technologie de Troyes, Troyes (FR); PhaseLab Instrument, Rosières-Près-Troyes (FR)

(72) Inventors: Julien VAILLANT, Sainte-Savine (FR); Aurélien BRUYANT, Saint-Andre-Les-Vergers (FR); Tsu-Heng WU, Yi-Lan City (TW)

(21) Appl. No.: 17/415,608

(22) PCT Filed: Dec. 17, 2019
(86) PCT No.: PCT/FR2019/053109

§ 371 Date: Jun. 17, 2021

(30) Foreign Application Priority Data
Dec. 18, 2018 (FR) 1873212

(51) Int. Cl. G01N 21/21; G01N 21/552

(52) U.S. Cl. CPC G01N 21/211; G01N 2201/0612; G01N 2201/0683; G01N 21/554

(57) ABSTRACT

The present invention relates to a laser device for polarisation interferometry using a temporally phase-modulated laser source as well as a passive phase delay element. This device, based on the interferences between the electric transverse TE and magnetic transverse TM components, allows improving the sensitivity of measuring apparatuses of the interferometer, ellipsometer or phase-sensitive surface plasmon resonance biosensor type, while proposing a compact and space-saving equipment.

The present invention generally relates to the field of interferometry and noise reduction in interferometers and other measurement devices derived from or coupled to interferometers such as ellipsometers or biosensors.

It is known to use interferometric devices for ellipsometric measurements, such as in the European patent EP1893977B1 or in the French patent FR2685962. It is also known to use interferometric devices for surface plasmon resonance (SPR) measurements allowing detecting molecular targets, for example in international patent applications WO2017153378 of the inventors of the present application and WO2009080998A2, or the American U.S. Pat. No. 7,233,396B2. These devices often implement bulky and expensive equipment, such as acousto-optic modulators, photo-elastic modulators, or Fresnel rhombohedra.

In both cases, ellipsometric measurements or surface plasmon resonance measurements, a high phase resolution is necessary in order to improve the sensitivity of the measurements. This high resolution can be attributed by a temporal modulation of the phase of the signals passing through the measuring devices. Indeed, an intrinsic advantage of the various phase modulation systems relative to other systems for measuring stationary signals without phase modulator is the noise reduction which a frequency analysis allows in the recovery of amplitude and phase, in particular thanks to the use of synchronous detections at the modulation frequencies of the detected interferometric signal. The American U.S. Pat. No. 5,485,271A describes an interferometric ellipsometer incorporating an electro-optic phase modulator. Other techniques allow a phase modulation obtained by modulation of the birefringence of a component of the measuring device, such as those described in the American U.S. Pat. No. 7,339,681B2, where a liquid crystal cell is used, or in the American U.S. Pat. No. 8,004,676B1, where a photo-elastic modulator is used. Also, a phase modulation can be obtained by modulating the wavelength of the source beam, as in the international patent application WO2017/153378, proposed by the present inventors, which describes a compact interferometer as well as a biochemical sensor derived therefrom, but which requires a particular optical chip producing two reflections, from two distant layers to carry out this modulation, which limits the application thereof to particular samples and does not allow any optical excitation condition.

It is also known to use interferometers called common path interferometers, in which the reference beam and the signal beam linked to a sample are displaced as much as possible along the same path, to reduce the noise of the interferometric measurements, because of the good immunity of this type of interferometers vis-à-vis the environmental vibrations.

It is also known to use asymmetric interferometers where the optical path difference between the two interfering arms is large enough for a low wavelength modulation of the used light source to result in a sufficient phase modulation in order to be able to extract an amplitude signal and a phase signal from the interferometric signal as explained by Vaillant et al. in “An unbalanced interferometer insensitive to wavelength drift”. Sensors and Actuators A: Physical, 268, 188-192 (2017). In this type of devices, however, the geometric path of the two beams is not common, thus limiting the stability of the system.

Furthermore, the drawback of the aforementioned techniques lies in the space requirement of the implementation device thereof as well as in their cost, in order to obtain high measurement accuracy and sensitivity. An interesting approach to minimize the noise of the interferometers consists in using a polarisation interferometer which measures the phase shift between two orthogonal components of the field, because in this case the path followed by the two components of the field can be relatively common. Nevertheless, the phase modulation of one component relative to the other requires an optical separation of the beams and a particular appliance such as those which are previously mentioned, such as for example a photo-elastic modulator.

The technical problem that the inventors propose to solve is to simplify the implementation and improve the sensitivity of interferometric measuring devices of the polarisation interferometer type, and the integration of this type of device as well. within ellipsometers than within SPR devices and to reduce the space requirement and weight thereof by avoiding the use of conventional active phase modulators and the use of movable parts to determine the state of the phase shift within of said polarisation interferometer.

In order to solve this problem while overcoming the aforementioned drawbacks, the applicant has developed a laser device for polarisation interferometry, adapted to deliver a temporally phase-modulated laser beam comprising:
a longitudinal single-mode laser source, powered by an electrical power supply current, and configured to deliver a polarised source laser beam S_{source} of wavelength λ, comprising two non-zero orthogonal rectilinear polarisation components, called respectively electric transverse, TE, and magnetic transverse, TM,
means for electronic temporal modulation of the laser source configured to drive a temporal modulation of the wavelength of the source laser beam S_{source},
a passive phase delay element producing two distinct optical paths for said TE and TM polarisation components, configured to receive the source laser beam S_{source} and introduce, due to the wavelength modulation of the source laser beam S_{source}, a temporally modulated phase shift between said TE and TM components to provide said temporally phase-modulated laser beam S_{modulated}.

As stated later in the description, the geometric path for the two TE and TM components of the field is advantageously constant.

Advantageously, the longitudinal single-mode laser source of the laser device can be a semiconductor laser which can be wavelength-modulated by the electrical current for powering the laser over a tunability range of less than one thousandth of the wavelength. This low tunability is achieved by most consumer laser diodes.

Preferably, the semiconductor laser which can constitute the longitudinal single-mode laser source of the laser device may be a vertical cavity surface emitting laser diode called VCSEL. However, in the absence of VCSEL, more widely tuneable and typically more expensive lasers can be used.

Moreover, the passive phase delay element of the laser device may comprise a component having a birefringence, in particular a birefringent crystal having an optical axis oriented along one of said TE or TM polarisation components of the source laser beam S_{source}.

The laser device may further comprise:
a reference beam splitter at the output of the phase delay element intended to split the beam into at least two portions S_{reference} and S_{modulated}, the first portion S_{reference} being a reference portion of the temporally phase-modulated laser beam S_{modulated}, and said beam splitter being configured to propagate the reference portion in a direction different from that of the temporally phase-modulated laser beam S_{modulated},
a reference photo-detector comprising an input intended to receive, via a reference polariser, said reference portion S_{reference}, and said reference photo-detector being configured to generate a first interferometric signal, in the form of a first modulated electrical signal I_{ref} representative of said reference portion S_{reference},
a reference electronic analysis unit configured to receive and analyse said electrical signal I_{ref} to extract an average phase shift Δ_{ref} between the two electric transverse TE and magnetic transverse TM orthogonal components of the reference portion S_{reference},
   said modulated electrical signal I_{ref} representative of said reference portion S_{reference} including an amplitude term A_{ref} proportional to the product of the amplitudes of the two electric transverse TE and magnetic transverse TM components and a phase term, said reference electronic analysis unit being configured to, by analysis of said electrical signal I_{ref}, extract the average phase shift Δ_{ref} between the two electric transverse TE and magnetic transverse TM components of the reference portion S_{reference}, and extract said amplitude term A_{ref}, and
   the reference electronic analysis unit being further configured to provide a correction coefficient to the means for temporal modulation of the source so as to adjust the temporal modulation of the laser source and to stabilise the average wavelength λ thereof by stabilisation of the average phase shift Δ_{ref}.

Advantageously, said reference electronic analysis unit is connected to the means for temporal modulation of the laser source so as to constitute a servo-control loop to stabilise the average phase shift Δ_{ref}.

Optionally, in order to facilitate the alignment, it may be useful to use beam splitters having reflective or anti-reflective treatments on different interfaces to avoid having multiple parasitic reflections. Other means can nevertheless be employed alone or in addition to suppress the multiple parasitic reflections, such as the use of non-parallel faces, or/and by spatially discriminating the first reflection and the first transmission, this including the use of thick blades.

The present application also proposes a polarisation interferometer configured to measure characteristics of a sample, comprising:
a laser device as previously described, adapted to deliver a temporally phase-modulated laser beam S_{modulated},
an opto-mechanical interface,
an analysis photo-detector and an analysis polariser,
an electronic analysis unit,
   in which
   said opto-mechanical interface is a simple support or an optical coupling system, which can include different optics, configured to transmit the temporally phase-modulated laser beam S_{modulated} towards the sample under the optical excitation conditions desired by the user such that the temporally phase-modulated laser beam S_{modulated} interacts with said sample so as to generate an output beam Sₛₐₘₚₗₑ,
   said analysis photo-detector comprises an input configured to receive, via the analysis polariser, said output beam Sₛₐₘₚₗₑ, and said analysis photo-detector being configured to generate a second interferometric signal, in the form of a second modulated electrical signal Iₛₐₘₚₗₑ, and
   said electronic analysis unit is connected to the analysis photo-detector and is configured to receive and analyse said modulated electrical signal Iₛₐₘₚₗₑ to determine characteristics of said sample.

More specifically, said opto-mechanical interface is a simple support, or an optical coupling system, which can include different optics, configured to transmit the temporally phase-modulated laser beam S_{modulated} towards the sample under the optical excitation conditions desired by the user so as to optically excite the sample so as to generate an output beam Sₛₐₘₚₗₑ.

More specifically, the modulated electrical signal Iₛₐₘₚₗₑ representative of the output beam Sₛₐₘₚₗₑ includes an amplitude term Aₛₐₘₚₗₑ proportional to the product of the amplitudes of the two electric transverse TE and magnetic transverse TM components of the output beam Sₛₐₘₚₗₑ and a phase term Δₛₐₘₚₗₑ including an optical phase shift increment Δ between the two electric transverse TE and magnetic transverse TM components induced by the sample. Consequently, the electronic analysis unit is configured to, by analysing said electrical signal Iₛₐₘₚₗₑ, extract said amplitude term Aₛₐₘₚₗₑ and said average phase term Δₛₐₘₚₗₑ between the two electric transverse TE and magnetic transverse TM components of the output beam Sₛₐₘₚₗₑ allowing determining the optical characteristics of said sample. When the laser device further comprises, as described above:
a reference beam splitter at the output of the phase delay element configured to split the beam into at least two portions S_{reference} and S_{modulated}, said portion S_{reference} being a reference portion of the temporally phase-modulated laser beam S_{modulated}, and being configured to propagate in a direction different from that of the temporally phase-modulated laser beam S_{modulated},
a reference photo-detector comprising an input configured to receive via a reference polariser said reference portion S_{reference}, and said reference photo-detector being configured to generate a first interferometric signal, in the form of a first modulated electrical signal I_{ref} representative of said reference portion S_{reference},
a reference electronic analysis unit configured to receive and analyse said electrical signal I_{ref} and determine Δₛₐₘₚₗₑ and Aₛₐₘₚₗₑ, then the optical phase shift increment Δ induced by the sample is obtained by the formula Δ=Δₛₐₘₚₗₑ−Δ_{ref} to within an additive constant.

The present application also proposes an ellipsometer configured to determine an ellipsometric parameter Δ_{ellipsometry} of a sample comprising an polarisation interferometer as previously described and in which:
the sample is capable of being placed at the opto-mechanical interface of the polarisation interferometer,
the interaction between the phase-modulated laser beam S_{modulated} and the sample is a reflection on the surface of said sample, and
   when the laser device further comprises, as described above:
a reference beam splitter at the output of the phase delay element configured to split the beam into at least two portions S_{reference} and S_{modulated}, said portion S_{reference} being a reference portion of the temporally phase-modulated laser beam S_{modulated}, and being configured to propagate in a direction different from that of the temporally phase-modulated laser beam S_{modulated},
a reference photo-detector comprising an input configured to receive, via a reference polariser, said reference portion S_{reference}, and said reference photo-detector being configured to generate a first interferometric signal, in the form of a first modulated electrical signal I_{ref} representative of said reference portion S_{reference},
a reference electronic analysis unit configured to receive and analyse said electrical signal I_{ref} and determine Δₛₐₘₚₗₑ and Aₛₐₘₚₗₑ, then
   the modulated electrical signal I_{ref} representative of said reference portion S_{reference}, includes an amplitude term A_{ref} proportional to the product of the amplitudes of the two electric transverse TE and magnetic transverse TM components and a phase term, and the reference electronic analysis unit is configured, by analysis of said electrical signal I_{ref}, to extract an average phase shift Δ_{ref} between the two electric transverse TE and magnetic transverse TM components of the reference portion S_{reference}, as well as said amplitude term A_{ref}, the ellipsometric parameter Δ_{ellipsometry} is obtained by the formula Δ_{ellipsometry}=Δₛₐₘₚₗₑ−Δ_{ref} to within an additive constant.

The phrase “the sample is capable of being placed at the opto-mechanical interface of the polarisation interferometer”, should mean that the opto-mechanical interface of the polarisation interferometer is capable of receiving the sample.

In a first variant of the proposed ellipsometer, said ellipsometer latter may further comprise a first additional detection channel, said first additional detection channel, said first additional detection channel comprising:
a first polarisation-selective beam splitter device, configured to take a portion of the output beam Sₛₐₘₚₗₑ and select one of the two electric transverse TE and magnetic transverse TM components of the output beam Sₛₐₘₚₗₑ in the form of a beam S_{tan Ψ} called polarised portion,
a photo-detector for complete ellipsometry configured to receive said polarised portion S_{tan Ψ} and generate an electrical signal I_{tan Ψ} characteristic of the light intensity of the polarised portion,
   where said first additional detection channel is configured to determine the ellipsometric parameter tan Ψ of the sample using the electrical signals Iₛₐₘₚₗₑ and I_{tan Ψ} respectively from the analysis photo-detector and the photo-detector for complete ellipsometry.

In a second variant of the proposed ellipsometer, different from the first variant described above, said ellipsometer may further comprise a second additional detection channel, said second additional detection channel comprising:
a second polarisation-selective beam splitter device configured to take a portion of the output beam Sₛₐₘₚₗₑ and select the two electric transverse TE and magnetic transverse TM components of the output beam Sₛₐₘₚₗₑ in the form of two beams S_{tan Ψ_TE} and S_{tan Ψ_TM} called respectively TE polarised portion and TM polarised portion,
two photo-detectors called TE photo-detector and TM photo-detector configured to receive respectively said TE polarised portion S_{tan Ψ_TE} and TM polarised portion S_{tan Ψ_TM} and to generate respectively an electrical signal I_{tan Ψ_TE} characteristic of the light intensity of the TE polarised portion S_{tan Ψ_TE} and an electrical signal I_{tan Ψ_TM} characteristic of the light intensity of the TM polarised portion S_{tan Ψ_TM},
   in which
   the second additional detection channel is configured to determine the ellipsometric parameter tan Ψ of the sample using the electrical signals I_{tan Ψ_TE} and I_{tan Ψ_TM} from the TE photo-detector and TM photo-detector.

The present application also proposes a biosensor of the surface plasm on resonance detection system type configured to determine characteristics of a sample consisting of a microfluidic layer MF, corresponding to the biological or biochemical medium to be analysed, the biosensor comprising:
a polarisation interferometer or an ellipsometer as previously described,
a removable biochip, which is supported by a prism, on which is deposited a thin resonant metal layer ME or another optical resonator also named ME capable of receiving the microfluidic layer MF to be analysed, the biochip being configured to constitute the sample to be analysed by the polarisation interferometer or the by the ellipsometer as previously described so as to intercept the temporally phase-modulated laser beam S_{modulated},
   and where:
the interaction between the temporally phase-modulated laser beam S_{modulated} and the sample consists of a resonant optical excitation of the resonator ME of the biochip in interaction with the microfluidic layer MF, producing said output beam Sₛₐₘₚₗₑ,
said output beam Sₛₐₘₚₗₑ characteristic of the sample is configured to be sensed by the analysis photo-detector,
the electronic analysis unit is configured to analyse said modulated electrical signal Iₛₐₘₚₗₑ representative of the output beam Sₛₐₘₚₗₑ generated by the analysis photo-detector in order to determine characteristics of said sample.

Other advantages and features of the present application will result from the following description, given by way of non-limiting example and made with reference to the appended figures:

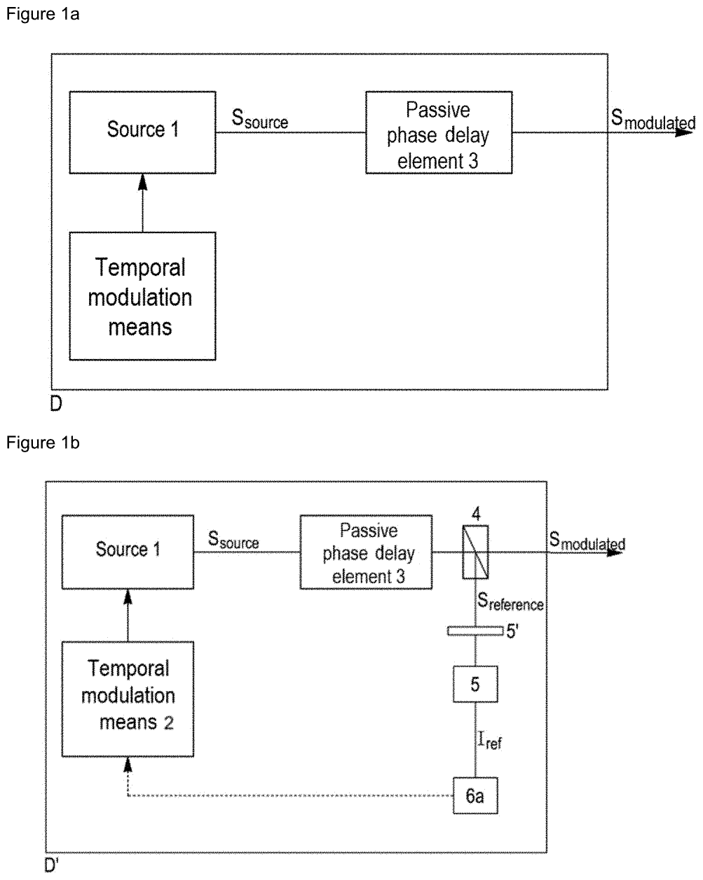

FIG. 1a schematically illustrates a first embodiment of a laser device as proposed;

FIG. 1b schematically illustrates a second embodiment of a laser device as proposed;

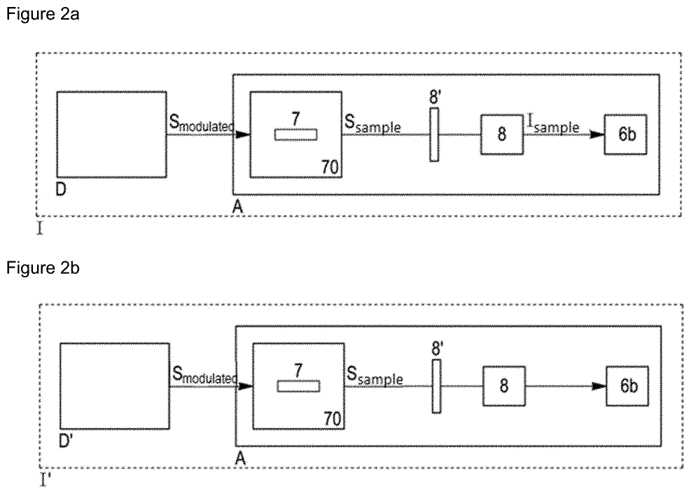

FIG. 2a schematically illustrates a first embodiment of a polarisation interferometer as proposed;

FIG. 2b schematically illustrates a second embodiment of a polarisation interferometer as proposed;

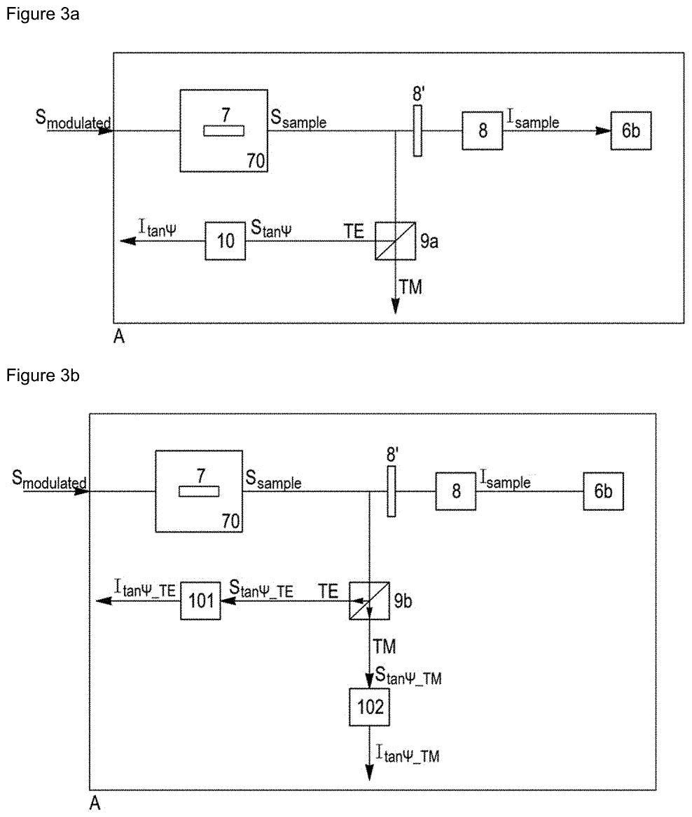

FIG. 3a schematically illustrates the portion named A of a polarisation interferometer as proposed for the implementation of a first variant of an ellipsometer for complete ellipsometry;

FIG. 3b schematically illustrates the portion named A of a polarisation interferometer as proposed for the implementation of a second variant of an ellipsometer for complete ellipsometry;

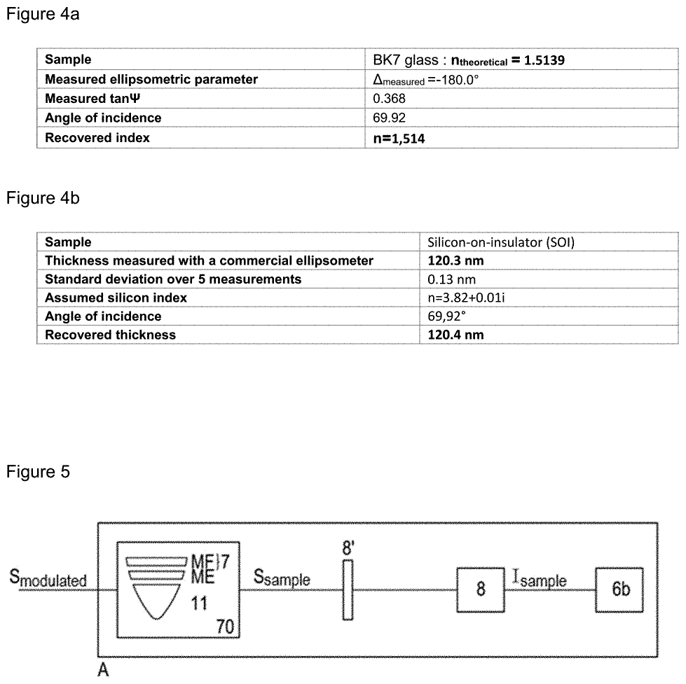

FIG. 4a shows experimental results obtained with an ellipsometer for complete ellipsometry;

FIG. 4b shows experimental results obtained with an ellipsometer for complete ellipsometry;

FIG. 5 schematically illustrates the portion named A of a polarisation interferometer as proposed for the implementation of a biosensor of the surface plasmon resonance detection system type;

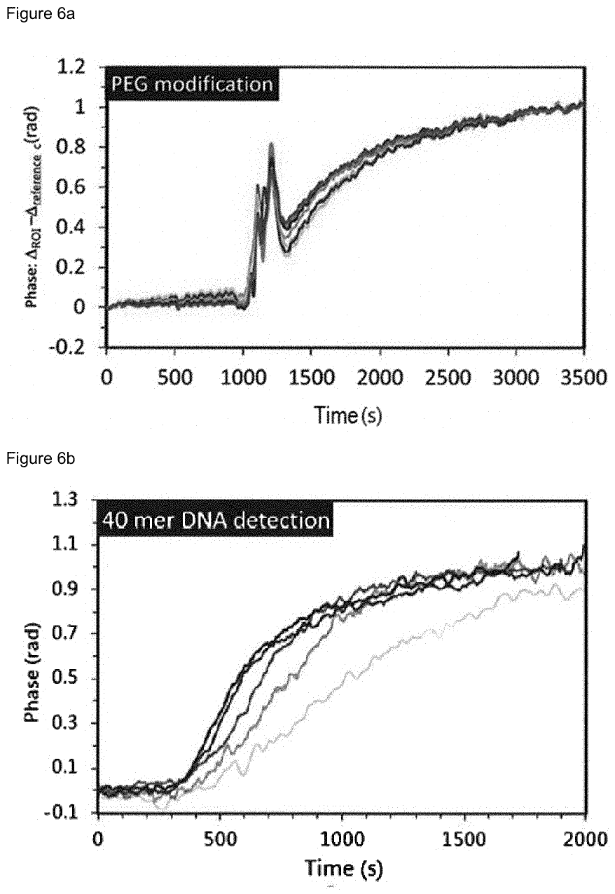

FIG. 6a shows experimental results obtained with a biosensor of the surface plasmon resonance detection system type as illustrated in FIG. 5; and

FIG. 6b shows experimental results obtained with a biosensor of the surface plasmon resonance detection system type as illustrated in FIG. 5.

FIGS. 1 to 6b are commented on in more detail in the following detailed description and examples, which illustrate the invention without limiting the scope thereof.

### DETAILED DESCRIPTION

With reference to FIG. 1a, a first embodiment of a laser device D comprises a longitudinal single-mode laser source 1. The term “longitudinal single-mode source” means a laser source comprising a single mode, or a laser source essentially having a main longitudinal mode and possibly other longitudinal modes which are sufficiently low, in comparison, to be ignored or filtered. The source is not necessarily transverse single-mode, in the case where a possibly complex field spatial distribution can be employed provided the field can be considered monochromatic. This laser source 1 is powered by an electrical power supply current. The wavelength λ of the single-mode laser source 1 is temporally modulated by temporal modulation means 2. The source laser beam S_{source} from the laser source 1 comprises two non-zero orthogonal rectilinear polarisation components, called electric transverse, TE, and magnetic transverse, TM. The source laser beam S_{source} passes through a passive phase delay element 3 which introduces a phase shift between the TE and TM components of the source laser beam S_{source}. Due to the temporal modulation of the wavelength of the laser source 1, the phase shift between the TE and TM components is also temporally modulated. Thus, the beam from the passive phase delay element 3 is a temporally phase-modulated laser beam S_{modulated}. The term “phase-modulated laser beam” means a laser beam in which the two polarisation components are modulated relative to each other. In said device, the phase modulation can be carried out by keeping a constant geometric path for the two components of the field and without an active modulation device other than the modulation of the laser source itself, the component where the modulation occurs being passive.

In order to be more accurate, when it is stated that the phase modulation can be carried out by keeping a constant geometric path for the two components of the field, it should be understood that the geometric path travelled by the two components of the field does not change over time, in particular at the element where the phase shift between these components occurs, that is to say in the passive phase delay element which is therefore fixed and advantageously monolithic for a better stability.

Preferably, the laser source 1 is a semiconductor laser, for example a vertical cavity surface emitting laser diode VCSEL.

Moreover, the temporal modulation of the wavelength of the laser source 1 can be performed by temporally modulating the electrical current powering the laser source 1. The temporal modulation of the wavelength of the laser source 1 is typically carried out over a tunability range of less than one thousandth of the wavelength. Thus, it is not necessary to resort to a birefringence modulation or another type of modulator to cause this phase modulation between said components of the field.

In particular, the passive phase delay element 3 may for example comprise or consist of a component having a birefringence, such as a birefringent crystal. In this particular case, the birefringent crystal advantageously has an optical axis along one of the two orthogonal transverse polarisation components of the source laser beam. Conventionally, these two polarisation components are called TE and TM for “electric transverse” and “magnetic transverse” with reference to a certain predetermined plane of incidence. The geometric path followed by the components of the TE and TM field can then be entirely common. The phase modulation between the two components of the field is thus generated independently of the nature of a possible sample intercepting the beam, and of the optics used to excite the sample such as lenses, prisms or coupling gratings.

By the term “common geometric path”, it should be understood that the light beams of the components of the TE and TM field are spatially superimposed. Such a configuration allows, for example, a pooling of the noise undergone by the different beams, making the device more stable, this despite the difference in the optical paths travelled by the TE and TM components. It is recalled that the optical path is defined by the product of the refractive index encountered by the geometric path.

The optics used to excite the sample, mentioned in the previous paragraph, allow, for example, defining the angle(s) of incidence and more generally the illumination conditions on the sample. The term “exciting the sample” means to generating, using the laser device, an electromagnetic field, within the sample.

Different elements can also be added to this device, in particular in order to stabilise or even control the average phase shift existing between the two components of the field or more generally to control the polarisation state emanating from the laser device. In particular, with reference to FIG. 1b, the laser device D can further have a reference arm comprising a reference beam splitter 4 which allows taking at the output of the passive phase delay element 3 a reference portion of the temporally phase-modulated laser beam S_{modulated}, called S_{reference}, propagating in a direction other than that of the temporally phase-modulated laser beam S_{modulated}. This reference portion S_{reference} is sent to a reference polariser 5′ through which the two TE and TM components of this reference portion S_{reference} interfere. Following the passage thereof through the reference polariser 5′, the reference portion S_{reference} is intercepted by a reference photo-detector 5 which delivers a modulated electrical signal I_{ref}.

This modulated electrical signal I_{ref} is received and analysed by a reference electronic analysis unit 6a. The modulated electrical signal I_{ref} includes a temporally phase-modulated interferometric term and having an amplitude A_{ref} proportional to the product of the amplitudes of the two electric transverse TE and magnetic transverse TM components of the reference portion S_{reference}.

Indeed, the modulated electrical signal I_{ref} represents the interferometric signal detected by the reference photo-detector, which can be written in the form:

I_{ref}∝E_{TE}²+E_{TM}²+2mE_{TE}E_{TM} cos(Δ_{mod}+Δ_{ref})=E_{TE}²+E_{TM}²+A_{ref}² cos(Δ_{mod}+Δ_{ref})

where
E_{TE} and E_{TM} are the amplitudes of the TE and TM components of the reference portion S_{reference},
M is a coefficient less than or equal to 1, and
A²_{ref}=2mE_{TE}E_{TM}, and
Δ_{mod} is a temporally modulated phase term, preferably sinusoidally, but not necessarily, depending on the choice of the current modulation function. The analysis of this type of modulated signal I_{ref} is in particular detailed in the references Al Mohtar, Abeer, et al. “Generalized lock-in detection for interferometry: application to phase sensitive spectroscopy and near-field nanoscopy.” Optics express 22.18 (2014): 22232-22245 and the U.S. Pat. No. 9,518,869B2 which proposes the use of a modified synchronous detection called generalized synchronous detection to perform the analysis. The use of generalized synchronous detection effectively allows extracting the amplitude A_{ref} and phase Δ_{ref} information, where Δ_{ref} characterises, in our case, the phase shift between said components TE and TM.

Thus, the reference electronic analysis unit 6a is capable of extracting from this electrical signal I_{ref}, comprising a phase-modulated interferometric term, the average phase shift Δ_{ref} between the two electric transverse TE and magnetic transverse TM components of the reference portion S_{reference}, and extracting said amplitude term A_{ref}. This method thus allows extracting said phase shift Δ_{ref} without ambiguity over the definition interval thereof. Otherwise, other extraction methods can be considered for particular temporal modulation functions, such as methods based on successive constant phase shifts, or the use of a ramp modulation called serrodyne ramp modulation. Particular attention should be given to the fact that the current modulation also causes a temporal modulation of the intensity of the laser, which causes a modulation of the intensity terms E_{TE}², E_{TM}² and A_{ref}² around their average values. This additional modulation can interfere with the measurement of the phase shift if it is not taken into account in the processing. A generalized synchronous detection, like the one mentioned, allows processing signals whose amplitude is also temporally modulated and allows overcoming this difficulty, ideally by adjusting the phase modulation depth. Otherwise, this modulation on said intensity terms E_{TE}², E_{TM}² and A_{ref}² can be neglected at the cost of a certain error, or else the measured intensity I_{ref} can be corrected to compensate for this modulation, knowing the used modulation function. The laser device thus constituted is named D′.

Furthermore, by stabilising the average phase shift Δ_{ref}, the reference electronic analysis unit 6a can provide a correction coefficient to the means 2 for temporal modulation of the laser source 1 so as to adjust the temporal modulation of the laser source 1 and to stabilise the average wavelength λ thereof. Thus, as indicated in dotted lines in FIG. 1b, the reference electronic analysis unit 6a can be connected to the means 2 for temporal modulation of the laser source so as to constitute a servo-control loop to stabilise the average phase shift to stabilise the average phase shift Δ_{ref}.

FIGS. 2a and 2b illustrate two polarisation interferometers, one, I, according to FIG. 2a, comprising a laser device D, and the other, I′, according to FIG. 2b, comprising a laser device D′. The interferometers I and I′ comprise, in a portion A at the output of the laser devices D, or D′, respectively, an opto-mechanical interface 70 illuminated by a temporally phase-modulated laser beam S_{modulated} from the laser device D, or D′, and transmitting the temporally phase-modulated laser beam S_{modulated} to a sample 7, which one wishes to optically measure certain characteristics by the relative phase shift and possibly the relative attenuation which it induces between the two components of the field. The temporally phase-modulated laser beam S_{modulated} then interacts with the sample 7 so as to generate an output beam Sₛₐₘₚₗₑ which can be transmitted, reflected or even diffracted by the sample. At the output of the opto-mechanical interface 70, the output beam Sₛₐₘₚₗₑ passes through an analysis polariser 8′ through which the two TE and TM components of the output beam Sₛₐₘₚₗₑ interfere. Following its passage through the analysis polariser 8′, the output beam Sₛₐₘₚₗₑ is intercepted by an analysis photo-detector 8 which delivers a modulated electrical signal Iₛₐₘₚₗₑ representative of the interference between the two TE and TM components of the output beam Sₛₐₘₚₗₑ. This modulated electrical signal Iₛₐₘₚₗₑ is received and analysed by an electronic analysis unit 6b. In particular, the modulated electrical signal Iₛₐₘₚₗₑ representative of the output beam Sₛₐₘₚₗₑ, includes a squared amplitude term Aₛₐₘₚₗₑ² proportional to the product of the amplitudes of the two electric transverse TE and magnetic transverse TM components of the output beam Sₛₐₘₚₗₑ, a phase term Δₛₐₘₚₗₑ, and a temporal modulation of the phase, that is to say of the phase shift between the two polarisation components. In addition to the temporal phase modulation, said phase shift includes an optical phase shift increment Δ between the two electric transverse TE and magnetic transverse TM components which is induced by the sample 7 during the reflection, transmission or diffraction resulting from the interaction with the sample, produced by one or several optical component(s) such as lenses, mirrors, or gratings, used in particular in order to convey light onto the solid, gaseous or liquid sample under the illumination conditions desired by the user. Mathematically, one can translate this property by:

Iₛₐₘₚₗₑ∝=I₀+Aₛₐₘₚₗₑ² cos(Δ_{mod}+Δₛₐₘₚₗₑ).

In particular also, the reference electronic analysis unit can be configured to, by analysing said electrical signal Iₛₐₘₚₗₑ, extract said amplitude term Aₛₐₘₚₗₑ and said average phase term Δₛₐₘₚₗₑ between the two electric transverse TE and magnetic transverse TM components of the output beam Sₛₐₘₚₗₑ allowing determining optical characteristics of said sample, specifically via the optical phase shift increment Δ, calculated, in the case where the interferometer is of the I′ type, that is to say in the case where it comprises a laser device with a reference arm D′, by: Δ=Δₛₐₘₚₗₑ−Δ_{ref} to within an easily determinable additive constant, for example by calibration on a sample with a known Δ.

The I′ type polarisation interferometer which is illustrated in FIG. 2b can further be used as an ellipsometer operating in reflection or in transmission. In both of these cases, a sample 7 is placed at the interface 70 of the polarisation interferometer I′. The phase-modulated laser beam S_{modulated}, incident on the sample 7, is reflected specularly on the surface thereof, or else is transmitted specularly by said sample for transmission, and propagates in an output beam Sₛₐₘₚₗₑ intercepted by the analysis polariser 8′ and the analysis photo-detector 8. The electronic analysis unit 6b allows, as explained above, extracting the ellipsometric parameter Δ_{ellipsometry}, by the formula Δ_{ellipsometry}=Δₛₐₘₚₗₑ−Δ_{ref} to within an additive constant.

FIG. 3a illustrates a first variant of the ellipsometer shown in FIG. 2b, in which the portion A comprises additional elements described below. Indeed, in this first variant, the previously described ellipsometer further comprises a first additional detection channel allowing determining an ellipsometric parameter tan Ψ of a sample 7. This additional channel comprises a first polarisation-selective beam splitter device 9a upstream of the analysis polariser 8′, which allows taking a portion of the output beam Sₛₐₘₚₗₑ and filtering one of the two electric transverse TE or magnetic transverse TM components of this portion of the output beam Sₛₐₘₚₗₑ in the form of a beam S_{tan Ψ} called polarised portion. This polarised portion S_{tan Ψ} is intercepted by a photo-detector for complete ellipsometry which generates an electrical signal I_{tan Ψ} characteristic of the light intensity of the polarised portion. The ellipsometric parameter tan Ψ of the sample is then determined using the quantities Aₛₐₘₚₗₑ and I_{tan Ψ} respectively from the analysis of the signal Iₛₐₘₚₗₑ from the analysis photo-detector 8 and the photo-detector for complete ellipsometry 10.

Indeed, the parameter tan Ψ is obtained, as conventionally in ellipsometry by the formula:

$$tan ψ = \vert \frac{{r}_{TM}}{{r}_{TE}} \vert ,$$

where r_{TM} and r_{TE} are the sample reflection coefficients carried by the TM and TE components of the output beam Sₛₐₘₚₗₑ. Thus, the parameter tan Ψ can be obtained, depending on the used experimental configuration, either by its square given by the equation:

$${( tan ψ )}^{2} ∝ \frac{{A}_{sample}^{2}}{{I}_{tan Ψ}} ,$$

if the TE component is recovered by the first additional detection channel, or by the equation:

$${( tan ψ )}^{2} ∝ \frac{{I}_{tan Ψ}}{{A}_{sample}^{2}} ,$$

if the TM component is recovered by the first additional detection channel.

FIG. 4 shows tables of measurements of glass and silica-on-silicon sample index and thickness obtained with an ellipsometer of the type in FIG. 3a.

FIG. 3b illustrates a second variant of the ellipsometer shown in FIG. 2b, in which the portion A comprises additional elements which are described below. Indeed, in this second variant, the ellipsometer which is previously described in FIG. 2b further comprises a second additional detection channel allowing determining an ellipsometric parameter tan Ψ of a sample 7. This additional detection channel comprises a second polarisation-selective beam splitter device 9b upstream of the analysis polariser 8′, which allows taking a portion of the output beam Sₛₐₘₚₗₑ and selecting the two electric transverse TE and magnetic transverse TM components of this portion of the output beam Sₛₐₘₚₗₑ in the form of two beams S_{tan Ψ_TE} and S_{tan Ψ_TM} called respectively TE polarised portion and TM polarised portion and propagating in two different directions. The TE polarised portion and the TM polarised portion are each received respectively by a photo-detector 101 and a photo-detector 102, called respectively TE photo-detector and TM photo-detector. The ellipsometric parameter tan Ψ of the sample is then determined using the electrical signals I_{tan Ψ_TE} and I_{tan Ψ_TM} from the TE photo-detector 101 and TM photo-detector 102.

FIG. 5 schematically illustrates a biosensor of the surface plasmon resonance detection system type, comprising a laser device D and capable of determining characteristics of a sample consisting of an optical resonator ME in interaction with a microfluidic layer MF, corresponding to the biological or biochemical medium to be analysed 7. This biosensor comprises in a portion A at the output of the laser device D (just like the interferometer I described above), and receiving a temporally phase-modulated laser beam S_{modulated}, a removable biochip 11 which can comprise a prism 110 or more generally a coupling optic capable of optically exciting the sample formed by the optical resonator ME in interaction with the microfluidic layer MF representing the medium 7 to be analysed. This biochip is positioned at an interface 70 and intercepts the temporally phase-modulated laser beam S_{modulated}. The latter excites a surface plasmon resonance wave at the surface of the metal layer ME of the biochip, which interacts with the medium to be analysed 7 at the interface with the microfluidic layer before being reflected, producing a beam Sₛₐₘₚₗₑ. The output beam Sₛₐₘₚₗₑ is intercepted by an analysis polariser 8′ followed by an analysis photo-detector 8 delivering an electrical signal Iₛₐₘₚₗₑ. An electronic analysis unit 6b connected to the analysis photo-detector 8 allows, as explained above, determining the characteristics of said sample 7. FIGS. 6a and 6b illustrate the type of measurements which can be obtained with a biosensor as previously described and illustrated in FIG. 5. These figures will be described in more detail in the examples presented below.

### EXAMPLES

### Example 1: Implementation of a Laser Device

A laser device is made as illustrated in FIGS. 1a to 1b to implement a polarisation interferometer which can be applied to a “complete” ellipsometric measurement or the phase-sensitive SPR detection, and allowing determining characteristics of a sample 7, for example of thin layer or multilayer type such as treated glass, or samples used in microelectronics, from the following elements:
longitudinal single-mode laser source 1: VCSEL referenced “VC670M-TO46GL” at 670 nm, of tunability in the range of 0.2 nm/mA;
means for electronic temporal modulation of the laser source 2: sinusoidal modulation of the injection current of the aforementioned VCSEL, with a sufficient average value i₀ for example equal to 4 mA and a preferably high frequency to reduce noise, up to 100 kHz or more (according to the capacities of the electronics), expressed by the relationship i(t)=i₀+β sin(Ωt);
passive phase delay element 3: yttrium vanadate crystal YVO4 with a birefringence equal to 0.22 and a length of 10 mm;
reference beam splitter 4: splitter blade such as the reference BSS04 (Thorlabs), or splitter cube;
reference polarizer 5′: polariser adapted to the used wavelength such as LPVISE050-A (Thorlabs);
reference photo-detector 5: photo-detector adapted to the used wavelength and used the modulation frequencies, for example a silicon photodiode for the visible, such as for example the reference PDA36A-EC (THORLABS);
reference electronic analysis unit 6a: electronic acquisition card, for example the reference NI USB-6363 (National Instrument).

The temporal modulation is typically carried out by a modulation of the injection current of the used longitudinal single-mode laser source. The modulation is preferably sinusoidal but other modulations can be used in order to carry out an interferometric detection with discrete or continuous phase shift. In the sinusoidal case, the modulation of the injection current i(t) is, as mentioned, of the type: i₀+β sin(Ωt). In the case of the type of aforementioned VCSEL, i₀ is typically in the range of 4 mA. The current modulation induces an optical power modulation which is approximately equal to: P(t)=P₀+γ sin(Ωt)=P₀ (1+μ sin(Ωt)), where P₀ is the power DC component, and μ*P₀, the AC amplitude of the modulation, Ω is the pulse of the modulation. This power modulation induces a wavelength modulation approximately equal to λ(t)=Δ₀+δ sin(Ωt), where λ₀ is the average wavelength and δ is the wavelength modulation depth. In the presence of such a modulation (of current, but also of power and wavelength), a phase modulation is created between the TE and TM components as soon as the beam passes through the aforementioned birefringent YVO4 crystal. The induced phase modulation is written: a sin (Ωt) in the sinusoidal case, with the phase modulation depth given by:

$$a = \frac{4 πΔ l δ}{{λ}_{0}^{2}} ,$$

where Δl is the optical path difference between the two components of the field within the delay element 3. In practice, it is interesting to work with a phase modulation a=3.83 rad as explained in another framework by Vaillant et al. in “An unbalanced interferometer insensitive to wavelength drift”. Sensors and Actuators A: Physical, 268, 188-192. In the above reference, this choice of phase modulation depth allows analysing the resulting interferometric signal more simply and simply extracting the amplitude information Aₛₐₘₚₗₑ and the desired phase term Aₛₐₘₚₗₑ.

In our case, in order to obtain the temporal phase modulation, the birefringence (nₑ−nₒ) and the length L of the YVO4 crystal are such that the optical path difference given by the product L(nₑ−nₒ) is at least in the order of magnitude of a millimetre, which corresponds to a cumulative phase shift between the TM component and the TE component in the range of 10,000 radians of visible light. This cumulative optical path difference is made with the previously mentioned components.

### Example 2: Measurement of a parameter Δ_{ellipsometry}

An ellipsometer is made as previously described and illustrated in FIG. 2b to determine a parameter Δ_{ellipsometry}, from the laser device described in Example 1.

In order to implement the aforementioned ellipsometer, one further uses:
an opto-mechanical interface 70 configured to transmit the temporally phase-modulated laser beam S_{modulated} exiting the laser device according to Example 1 towards a sample 7 such that the temporally phase-modulated laser beam S_{modulated} interacts with the sample so as to generate an output beam Sₛₐₘₚₗₑ;
an analysis polarizer 8′: LPVISE050-A polariser (Thorlabs);
an analysis photo-detector 8: silicon photodiode, for example the reference PDA36A-EC (THORLABS);
an electronic analysis unit 6b: electronic acquisition card, for example the reference NI USB-6363 (National Instrument).

The ellipsometric parameter Δ_{ellipsometry} is obtained by the formula Δ_{ellipsometry}=Δₛₐₘₚₗₑ−Δ_{ref} to within an additive constant, with Δₛₐₘₚₗₑ the extracted phase parameter of the electrical signal Iₛₐₘₚₗₑ from the analysis photo-detector 8, and corresponding to the phase shift between the TE and TM components of the output beam Sₛₐₘₚₗₑ induced by the sample.

### Example 3: Ellipsometric Measurements of Indexes and Thicknesses of Thin-Layer Type Multilayer Samples

An ellipsometer is made as illustrated in FIG. 3a to determine Δ_{ellipsometry} and tan Ψ parameters, from the ellipsometer described in Example 2, and further comprising:
a first polarisation-selective beam splitter device 9a, a simple splitter such as BSS04 (Thorlabs) followed by polarisers such as LPVISE050-A (Thorlabs);
a photo-detector for complete ellipsometry 10.

The ellipsometric parameter Δ_{ellipsometry} is obtained as in Example 2. The parameter (tan Ψ)² can be obtained, according to the used experimental configuration, either by the equation (tan ψ)²

$$∝ \frac{{A}_{sample}^{2}}{{I}_{tan Ψ}} ,$$

if the TE component is recovered by the first additional detection channel, or the reverse if the TM component is recovered by the first additional detection channel. In practice, the coefficient of proportionality between (tan Ψ)² and A²ₛₐₘₚₗₑ/I_{tan ψ} can be predetermined simply by a calibration experiment on a known sample. In this example, the coefficient of proportionality is previously determined by measuring the parameter tan Ψ on a known sample.

From the Δ_{ellipsometry} and tan Ψ parameters, it is possible to determine, as conventionally in ellipsometry, the complex optical index or the thickness of the known thin layer or other unknown parameters linked for example to the roughness. FIG. 4 illustrates a set of experimental results made with the previously described ellipsometer.

### Example 4: Ellipsometric Measurements of Indexes and Thicknesses of Thin-Layer or Multilayer Stack Type Samples

An ellipsometer is made as illustrated in FIG. 3b to determine Δ_{ellipsometry} and tan Ψ parameters, from the ellipsometer described in Example 2, and further comprising:
a second polarisation-selective beam splitter device 9b: simple splitter such as BSS04 (Thorlabs) followed by polarisers such as LPVISE050-A (Thorlabs), or simple splitters operating at Brewsterian incidence;
two photo-detectors 101 and 102: silicon photodiodes, possibly amplified, for example the reference PDA36A-EC (THORLABS).

The ellipsometric parameter Δ_{ellipsometry} is obtained as in Examples 2 and 3. As described above, the parameter tan Ψ is directly obtained by its square:

$${( tan ψ )}^{2} ∝ \frac{{I}_{tan Ψ\_ TM}}{{I}_{tan Ψ\_ TE}} ,$$

With I_{tan Ψ_TE} and I_{tan Ψ_TM} the signals from the TE photo-detector and TM photo-detector. The coefficient of proportionality is equal to unity if the beams are shared in identical proportions. In practice, the coefficient can be predetermined simply by a calibration experiment, for example on a known sample. From the Δ_{ellipsometry} and tan Ψ parameters, it is possible to determine, as conventionally in ellipsometry, the complex index and the thickness of layers within the measured sample.

### Example 5: Surface Plasmon Resonance Type Measurements and Detection of Thiolated PEG (Poly-Ethylene Glycol-SH)

A biosensor as illustrated in FIG. 5 is made for application to the surface plasmon resonance type detection allowing measuring parameters of a sample 7 in order to monitor herein the deposition of thiolated PEG thereon. The sample consists of an optical resonator (ME) formed herein of a gold layer of about 45 nm interacted with the solution containing the thiolated PEG (poly-ethylene glycol-SH) present within the microfluidic layer. This biosensor illustrated in FIG. 5 is made from the laser device described in Example 1, by adding thereto as illustrated in FIG. 5:

an opto-mechanical interface 70: support;

an analysis polarizer 8′: LPVISE050-A polariser (Thorlabs);

an analysis photo-detector 8: silicon photodiode, for example the reference PDA36A-EC (THORLABS);

an electronic analysis unit 6b: electronic acquisition card, for example the reference NI USB-6363 (National Instrument);

the preferably removable biochip 11 disposed on the interface 70 and comprising a prism 110 on which a gold metal layer ME (45 nm thick), which is capable of receiving the thiolated PEG layer constituting the sample to be analysed, is deposited.

In this specific case, the analysis photo-detector 8 is an imager allowing a multi-point measurement. The biosensor is used in a configuration called Kretschmann configuration via the prism (110). The parameter Δ=Δₛₐₘₚₗₑ−Δ_{ref} which can be determined thanks to the polarisation interferometer of the biosensor as previously described is generally not accessible with other types of SPR measuring devices. FIG. 6a illustrates the measurement of the functionalisation of the gold layer in contact with the thiolated PEG microfluidic layer. This type of measurement allows obtaining optogeometric information on the deposited layer and herein in particular knowing the time after which the reaction does not evolve more than slightly (e.g. 3500 seconds).

### Example 6: Surface Plasmon Resonance Type Measurements and Detection of Different Amounts of 40 Mer DNA

FIG. 6b illustrates measurements aiming at detecting different amounts of DNA binding to the surface (phase sensorgrams), via the variations of the parameter Δ over time within the different regions of interest. The comparison with the reference signals allows avoiding fluctuations in amplitude and phase parameters unrelated to the target itself, such as environmental variations such as temperature variations at the chip itself. The used microfluidic layer is composed herein of complementary DNA strands of 40 mer codons. The curves of different colour levels (black to light grey) thus have a characteristic variation kinetics of the analysed concentrations, herein from 25 nM to 500 nM. The observed curves follow a conventional isothermal Langmuir type adsorption process.

It should be noted that the above SPR type measurements, performed with a laser device according to Example 1, can also be carried out using a laser device as proposed in the present application having other characteristics, for example, with a laser source operating at any other wavelength, such as in the mid-infrared or near infrared, for example with a VCSEL operating at a wavelength of about 850 mm with the same phase modulation, i.e. 3.84rad, and by adapting the current modulation in mA to carry out this phase modulation, as well as the components of the system to operate at this wavelength.

Other embodiments can be considered. For example, another embodiment can comprise multi-angle measurements, where, in both cases of applications to ellipsometry or the detection by surface plasmon resonance, measurements according to several angles of incidence are performed, or conversely, the beam at the output of the measured sample is split after interaction with the sample according to several different angles. In the case of the plurality of angles of incidence, a cylindrical lens can for example be placed upstream of the interface receiving the samples to be tested in order to obtain a beam focused in the plane of incidence, thus giving a plurality of angles of incidence illuminating the sample, the latter reflecting the extended beam received in several directions sensed by a linear detector (of the diode array type for example).

Also, as mentioned in Example 6, the analysis photo-detectors 8, photo-detector for complete ellipsometry 10, and photo-detector TE and photo-detector TM 101 and 102 can be two-dimensional sensors allowing imaging samples to be measured and obtaining two-dimensional maps of the characteristics of these samples. In this case, all types of two-dimensional sensors can be used, such as CCD or CMOS sensors, or photo-detectors having a reduced number of detection areas such as quadrant photodiodes which can also help in centring the beam.

Also, ellipsometric measurements in transmission can be carried out in the case of a sufficiently transparent sample. A plurality of laser optical sources can also be employed to extend the analysis spectral range. Also, the ellipsometric analysis can be extended to obtain additional information on the sample from the ellipsometric parameters determined from a model which can take into account in particular the density or roughness of a layer.

Also, the SPR device being able to integrate an ellipsometric measurement, the latter can be used to determine the characteristics of the layers composing the biochip, for example the thickness of the gold deposit, or the thickness (or the density) of a functionalisation layer, or else the molecular layers from the analyte passing through the microfluidic layer clinging to the surface. Thus the biochip can be prepared for the measurement of any biochemical species (pathogens, proteins, bacteria, biomarkers) by using the ellipsometric measuring device at each step of the functionalisation process, which is typically carried out on the SPR biochips to allow the detection of a target in particular using antibodies, DNA or aptamers.

The examples of optomechanical interfaces 70 given in this description are not limiting. Thus, in addition to a simple support as in Example 5, or a coupling prism provided or not with a resonant element as in Example 5, coupling gratings or lenses could be used to optically excite a resonance of the sample. In particular, the SPR devices typically require a coupling element as in the examples given in this description. The coupling element allows obtaining, if necessary, a plurality of excitation angles. The privileged excitation of the SPR devices is an excitation at a supercritical angle known as the Kretschmann configuration. Thus the essential role of the opto-mechanical interface is to define the angle(s) of incidence and more generally the illumination conditions on the sample.

1. A laser device (D) for polarisation interferometry adapted to deliver a temporally phase-modulated laser beam (S_{modulated}) and comprising:
a longitudinal single-mode laser source, powered by an electrical power supply current, and configured to deliver a polarised source laser beam (S_{source}) of wavelength (λ), comprising two non-zero orthogonal rectilinear polarisation components, called respectively electric transverse, TE, and magnetic transverse, TM,
means for electronic temporal modulation of the laser source configured to drive a temporal modulation of the wavelength of the source laser beam (S_{source}), and
a passive phase delay element, producing two distinct optical paths for said TE and TM polarisation components, configured to receive the source laser beam (S_{source}) and introduce, due to the wavelength modulation of the source laser beam (S_{source}), a temporally modulated phase shift between said TE and TM components to provide said temporally phase-modulated laser beam (S_{modulated}).

2. The laser device (D) according to claim 1, wherein the laser source is a semiconductor laser which can be wavelength-modulated by the electrical current for powering the laser over a tunability range of less than one thousandth of the wavelength.

3. The laser device (D) according to claim 2, wherein the semiconductor laser type source is a vertical cavity surface emitting laser diode VCSEL.

4. The laser device (D) according to claim 1, wherein the phase delay element comprises a component having a birefringence.

5. The laser device (D) according to claim 4, wherein the phase delay element comprises a birefringent crystal having an optical axis oriented along one of said TE or TM polarisation components of the source laser beam (S_{source}).

6. The laser device (D′) according to claim 1, further comprising:
a reference beam splitter at the output of the phase delay element intended to split the beam into at least two portions (S_{reference}) and (S_{modulated}), the first portion (S_{reference}) being a reference portion of the temporally phase-modulated laser beam (S_{modulated}), and said beam splitter being configured to propagate the reference portion in a direction different from that of the temporally phase-modulated laser beam (S_{modulated}),
a reference photo-detector comprising an input intended to receive, via a reference polariser, said reference portion (S_{reference}), and said reference photo-detector being configured to generate a first interferometric signal, in the form of a first modulated electrical signal (I_{ref}) representative of said reference portion (S_{reference}),
a reference electronic analysis unit (6a) configured to receive and analyse said electrical signal (I_{ref}) to extract an average phase shift (Δ_{ref}) between the two electric transverse TE and magnetic transverse TM orthogonal components of the reference portion (S_{reference}),
the modulated electrical signal (I_{ref}) representative of said reference portion (S_{reference}) including an amplitude term (A_{ref}) proportional to the product of the amplitudes of the two electric transverse TE and magnetic transverse TM components and a phase term,
the reference electronic analysis unit being configured to, by analysis of said electrical signal (I_{ref}), deduce therefrom the average phase shift (Δ_{ref}) between the two electric transverse TE and magnetic transverse TM components of the reference portion (S_{reference}), and extract said amplitude term (A_{ref}), and
the reference electronic analysis unit being further configured to provide a correction coefficient to the means for temporal modulation of the laser source so as to adjust the temporal modulation of the laser source and to stabilise the average wavelength λ thereof by stabilisation of the average phase shift (Δ_{ref}).

7. The laser device (D′) according to claim 6, wherein said reference electronic analysis unit is connected to the means for temporal modulation of the laser source so as to constitute a servo-control loop to stabilise the average phase shift (Δ_{ref}).

8. A polarisation interferometer I configured to measure characteristics of a sample, comprising:
a laser device (D) or (D′) according to claim 1, adapted to deliver a temporally phase-modulated laser beam (S_{modulated});
an opto-mechanical interface:
an analysis photo-detector and an analysis polariser;
an electronic analysis unit;
wherein
said opto-mechanical interface being a simple support or an optical coupling system, which can include different optics, configured to transmit the temporally phase-modulated laser beam (S_{modulated}) towards the sample under the optical excitation conditions desired by the user so as to optically excite the sample so as to generate an output beam (Sₛₐₘₚₗₑ),
the analysis photo-detector comprises an input configured to receive, via the analysis polariser, said output beam (Sₛₐₘₚₗₑ), and said analysis photo-detector being configured to generate a second interferometric signal, in the form of a second modulated electrical signal (Iₛₐₘₚₗₑ),
said electronic analysis unit is connected to the analysis photo-detector and is configured to receive and analyse said modulated electrical signal (Iₛₐₘₚₗₑ) to determine characteristics of said sample.

9. The polarisation interferometer I according to claim 8, configured to determine optical characteristics of said sample wherein:
the electronic analysis unit is configured to, by analysis of said electrical signal (Iₛₐₘₚₗₑ), extract an amplitude term (Aₛₐₘₚₗₑ) and an average phase term (Δₛₐₘₚₗₑ) between the two electric transverse TE and magnetic transverse TM components of the output beam (Sₛₐₘₚₗₑ) allowing determining the optical characteristics of said sample,
and,
when the polarisation interferometer comprises:
a reference beam splitter at the output of the phase delay element configured to split the beam into at least two portions (S_{reference}) and (S_{modulated}), said portion (S_{reference}) being a reference portion of the temporally phase-modulated laser beam (S_{modulated}), and being configured to propagate in a direction different from that of the temporally phase-modulated laser beam (S_{modulated}),
a reference photo-detector comprising an input configured to receive via a reference polariser said reference portion (S_{reference}), and said reference photo-detector being configured to generate a first interferometric signal, in the form of a first modulated electrical signal (I_{ref}) representative of said reference portion (S_{reference}),
a reference electronic analysis unit configured to receive and analyse said electrical signal (I_{ref}), said reference electronic analysis unit is further configured to extract an average phase shift (A_{ref}) between the two electric transverse TE and magnetic transverse TM components of the reference portion (S_{reference}), so as to calculate, to within an additive constant, an optical phase shift increment (Δ) induced by the sample by the formula Δ=Δₛₐₘₚₗₑ−Δ_{ref}.

10. An ellipsometer configured to determine an ellipsometric parameter (Δ_{ellipsometry}) of a sample comprising an polarisation interferometer I according to claim 9, and wherein:
the opto-mechanical interface of the polarisation interferometer (I) is capable of receiving the sample,
the interaction between the phase-modulated laser beam (S_{modulated}) and the sample is a reflection on the surface of said sample, and when the laser device is a laser device D′, comprising:
a reference beam splitter at the output of the phase delay element configured to split the beam into at least two portions (S_{reference}) and (S_{modulated}), said portion (S_{reference}) being a reference portion of the temporally phase-modulated laser beam (S_{modulated}), and being configured to propagate in a direction different from that of the temporally phase-modulated laser beam (S_{modulated}),
a reference photo-detector comprising an input configured to receive, via a reference polariser, said reference portion (S_{reference}), and said reference photo-detector being configured to generate a first interferometric signal, in the form of a first modulated electrical signal (I_{ref}) representative of said reference portion (S_{reference}),
a reference electronic analysis unit configured to receive and analyse said electrical signal (I_{ref}), then the modulated electrical signal (I_{ref}) representative of said reference portion (S_{reference}), includes an amplitude term (A_{ref}) proportional to the product of the amplitudes of the two electric transverse TE and magnetic transverse TM components and a phase term, and
the reference electronic analysis unit is configured, by analysis of said electrical signal (I_{ref}), to extract an average phase shift (Δ_{ref}) between the two electric transverse TE and magnetic transverse TM components of the reference portion (S_{reference}), as well as said amplitude term (A_{ref}), the ellipsometric parameter (Δ_{ellipsometry}) is obtained by the formula (Δ_{ellipsometry})=(Δₛₐₘₚₗₑ)−(Δ_{ref}) to within an additive constant.

11. The ellipsometer according to claim 10, configured to determine an ellipsometric parameter (tan Ψ) of a sample and comprising a first additional detection channel, said first additional detection channel comprising:
a first polarisation-selective beam splitter device, configured to take a portion of the output beam (Sₛₐₘₚₗₑ) and select one of the two electric transverse TE and magnetic transverse TM components of the output beam (Sₛₐₘₚₗₑ) in the form of a beam (S_{tan Ψ}) called polarised portion,
a photo-detector for complete ellipsometry configured to receive said polarised portion (S_{tan Ψ}) and generate an electrical signal (I_{tan Ψ}) characteristic of the light intensity of the polarised portion,
where said first additional detection channel is configured to determine the ellipsometric parameter (tan Ψ) of the sample using the electrical signals (Iₛₐₘₚₗₑ) and (I_{tan Ψ}) respectively from the analysis photo-detector and the photo-detector for complete ellipsometry.

12. The ellipsometer according to claim 10, configured to determine an ellipsometric parameter (tan Ψ) of a sample and further comprising a second additional detection channel, said second additional detection channel comprising:
a second polarisation-selective beam splitter device configured to take a portion of the output beam (Sₛₐₘₚₗₑ) and select the two electric transverse TE and magnetic transverse TM components of the output beam (Sₛₐₘₚₗₑ) in the form of two beams (S_{tan Ψ_TE}) and (S_{tan Ψ_TM}) called respectively TE polarised portion and TM polarised portion,
two photo-detectors and called TE photo-detector and TM photo-detector configured to receive respectively said TE polarised portion (S_{tan Ψ_TE}) and TM polarised portion (S_{tan Ψ_TM}) and to generate respectively an electrical signal (I_{tan Ψ_TE}) characteristic of the light intensity of the TE polarised portion (S_{tan Ψ_TE}) and an electrical signal (I_{tan Ψ_TM}) characteristic of the light intensity of the TM polarised portion (S_{tan Ψ_TM}),
where the second additional detection channel is configured to determine the ellipsometric parameter (tan Ψ) of the sample using the electrical signals (|I_{tan Ψ_TE}) and (I_{tan Ψ_TM}) from the TE photo-detector and TM photo-detector.

13. A biosensor of the surface plasmon resonance detection system type configured to determine characteristics of a sample consisting of a microfluidic layer (MF), corresponding to the biological or biochemical medium to be analysed, the biosensor comprising:
a polarisation interferometer (I) according to claim 8
a removable biochip, which is supported by a prism, on which is deposited a thin resonant metal layer (ME) or another optical resonator also named (ME) capable of receiving the microfluidic layer (MF) to be analysed, the biochip being configured to constitute the sample to be analysed by the polarisation interferometer so as to intercept the temporally phase-modulated laser beam (S_{modulated}) in which:
the interaction between the temporally phase-modulated laser beam (S_{modulated}) and the sample consists of a resonant optical excitation of the resonator (ME) of the biochip in interaction with the microfluidic layer (MF), producing said output beam (Sₛₐₘₚₗₑ)
said output beam (Sₛₐₘₚₗₑ) characteristic of the sample is configured to be sensed by the analysis photo-detector
the electronic analysis unit is configured to analyse said modulated electrical signal (Iₛₐₘₚₗₑ) representative of the output beam (Sₛₐₘₚₗₑ) generated by the analysis photo-detector in order to determine characteristics of said sample.

14. A biosensor of the surface plasmon resonance detection system type configured to determine characteristics of a sample consisting of a microfluidic layer (MF), corresponding to the biological or biochemical medium to be analysed, the biosensor comprising:
an ellipsometer according to claim 10;
a removable biochip, which is supported by a prism, on which is deposited a thin resonant metal layer (ME) or another optical resonator also named (ME) capable of receiving the microfluidic layer (MF) to be analysed, the biochip being configured to constitute the sample to be analysed by the ellipsometer so as to intercept the temporally phase-modulated laser beam (S_{modulated}) in which:
the interaction between the temporally phase-modulated laser beam (S_{modulated}) and the sample consists of a resonant optical excitation of the resonator (ME) of the biochip in interaction with the microfluidic layer (MF), producing said output beam (Sₛₐₘₚₗₑ)
said output beam (Sₛₐₘₚₗₑ) characteristic of the sample is configured to be sensed by the analysis photo-detector
the electronic analysis unit is configured to analyse said modulated electrical signal (Iₛₐₘₚₗₑ) representative of the output beam (Sₛₐₘₚₗₑ) generated by the analysis photo-detector in order to determine characteristics of said sample.
